(19) United States
(12) Patent Application Publication
(10) Pub. No.: US 2005/0208765 A1
(43) Pub. Date: Sep. 22, 2005

(54) Method for the formation of silicides

(75) Inventors: Francois Wacquant, Saint Ismier (FR); Christophe Regnier, Saint Hilaire Du Touvet (FR); Benoit Froment, Grenoble (FR); Damien Lenoble, Gieres (FR); Rebha El Farhane, Grenoble (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignees: STMicroelectronics, SA, Montrouge (FR); Koninklijke Philips Electronics N.V., Eindhoven (NL)

(21) Appl. No.: 10/871,542

(22) Filed: Jun. 18, 2004

(30) Foreign Application Priority Data
Jun. 20, 2003 (FR) 03 07475

(51) Int. Cl. H01L 29/94; H01L 21/4763; H01L 31/119

(52) U.S. Cl. 438/664; 438/581; 257/388; 257/412

(57) ABSTRACT

A process for forming a silicide on top of at least one silicon portion on the surface of a semiconductor wafer, comprising the following steps: a) implanting, at a defined depth in the silicon portion, through a dielectric layer, of ions that have the property of limiting the silicidation of metals; b) performing heat treatment; c) depositing a metal layer, the metal being capable of forming a silicide by thermal reaction with the silicon; d) performing rapid thermal processing suitable for siliciding the metal deposited at step c); and e) removing the metal that has not reacted to the thermal processing of step d). Advantageously, the thickness of the silicide layer created at step d) is controlled by a suitable choice of the depth of the implantation carried out in step a).

### BACKGROUND OF THE INVENTION

1. Field of the Invention

The present invention relates to the fabrication of semiconductor devices and more particularly to the formation of suicides by thermal reaction with silicon.

The invention is especially applicable in the fabrication of MOS (Metal Oxide Semiconductor) transistors in all technologies using silicides, in particular in 0.18-μm, 0.12-μm, 90-nm, or 65-nm technologies.

2. Description of the Related Art

MOS transistors are important components of semiconductor devices, and the electrical performance of the gate of the MOS transistors directly affects the quality of these devices. The gate of an MOS transistor typically comprises a polycrystalline silicon (polysilicon) layer or an amorphous silicon layer used as main conducting layer, and sometimes a silicide layer, for example a cobalt silicide (CoSi₂) layer, stacked on the main conducting layer. Likewise the source and drain active regions of the MOS transistor comprise a doped silicon layer, which may be covered with a silicide layer. These silicide layers provide good ohmic contact and consequently reduce the layer resistances of the MOS transistor and increase the operational speed of the semiconductor device that incorporates it.

It is known that siliciding processes, for example those in which cobalt (Co) is deposited, are sensitive to the presence of defects of the surface of the silicon, in particular the presence of organic residues. Such residues may stem from a resist layer implanted into the silicon during the steps of forming the source and drain active regions by the implantation of dopant species through the edges of the said resist layer used as implantation mask. They may be the cause of what is called a “salicide cut”.

In the current state of the art, defects of this type are eliminated by sputter etching, comprising bombardment with argon (Ar) ions. This etching, which is carried out before the actual siliciding process, allows the formation, without cuts, of the silicide on the gates and on the active regions of MOS transistors.

However, such an Ar ion bombardment induces junction leakage. In addition, it results in re-sputtering of silicon on the sidewalls of the spacers, which may result in a short circuit between the gate and the source and/or drain active regions (a phenomenon called “bridging”). Finally, it also leads to degradation of the silicide spikes.

Furthermore, because of their spiking, the thickness of the silicide layers formed using the known techniques of the prior art is poorly controlled, essentially because it results from the conditions under which the actual siliciding step is carried out (temperature and duration of a siliciding heat treatment).

### BRIEF SUMMARY OF THE INVENTION

One embodiment of the invention provides a process for the formation of silicides that alleviates the aforementioned drawbacks of the prior art.

In particular, one embodiment of the present invention provides a process for forming a silicide on top of at least one silicon portion on the surface of a semiconductor wafer, comprising the following steps:
a) implanting, at a defined depth in the silicon portion, ions that have the property of limiting the silicidation of metals;
b) performing a heat treatment;
c) depositing a metal layer, said metal being capable of forming a silicide by thermal reaction with the silicon;
d) performing rapid thermal processing suitable for siliciding the metal deposited at step c); and
e) removing the metal that has not reacted to the thermal processing of step d).

The thickness of the suicide created at step d) is controlled by an appropriate choice of the depth of the implantation carried out at step a), it being in fact found that this is itself determined by the conditions of the said implantation.

The process applies especially to the fabrication of a MOS transistor, the silicon portion(s) to be silicided typically being the gate region, the source region and/or the drain region.

This is why another aspect of the invention relates to an MOS transistor comprising a silicide layer on top of a defined region and furthermore including ions implanted in the said region just below the silicide layer, the said ions having the property of limiting the silicidation of metals.

Yet another aspect of the invention relates to a semiconductor device comprising such a MOS transistor.

The implantation carried out at step a) may advantageously, but not necessarily, be a pre-amorphization implantation, consisting, for example of bombarding the structure with non-dopant ions or PAIs (pre-amorphization implants). The implanted species is then preferably a heavy species, which favors amorphization of the silicon. Such pre-amorphization implantation thus makes it possible to destroy the organic residues arising from the unintentional implantation of the resist into the silicon, without modifying the electrical behavior of the underlying portions.

A non-dopant species is either an inert species or a rare gas (last column in the Periodic Table of Elements), or both at the same time. The “inert” character of the implanted species relates to the silicon substrate on which the MOS transistor is placed, in the sense that an inert species is one which has the same valency as the said substrate. An inert species typically used in microelectronics is germanium (Ge). Examples of rare gases that can be used instead of Ge are xenon (Xe) and argon (Ar).

The “heavy” character of the implanted species relates to its atomic mass, for example expressed in atomic mass units (amu), which is the IUPAC (International Union of Pure and Applied Chemistry) unit based on the atomic mass of the carbon-12 isotope. For example, the atomic mass of Ge is 72.61 amu, that of Ar is 39.948 amu and that of Xe is 131.29 amu. The heavier the species, the lower the implanted dose may be.

The species indicated in the above two paragraphs are known to have the property of limiting the silicidation of metals. According to one advantage of the invention, by controlling the implantation depth of the ions of such a species, via an appropriate choice of the conditions under which the implantation is carried out in step a), it is possible to control the thickness of the silicide layer created at step d).

Metals that have the property of forming a silicide by thermal processing with silicon are, for example, Co, nickel (Ni), platinum (Pt) and titanium (Ti). Their corresponding silicides are CoSi₂, PtSi, NiSi, and TiSi₂ respectively. Such metals may be deposited, for example, by LPCVD (Low-Pressure Chemical Vapor Deposition) or by a sputtering process.

Advantageously, the implantation of step a) may take place through a dielectric layer, which makes it possible to limit the channeling of the ions into the silicon. This dielectric layer is removed during a removal step that comes between steps b) and c).

Moreover, the heat treatment of step b) has the function of repairing the defects generated in the structure owing to the ion implantation.

Step b) may be carried out by an annealing operation in order to activate dopant species pre-implanted in the silicon (especially in the source and drain regions of the MOS transistors of the wafer). Such an annealing step is conventional in the fabrication of an MOS transistor. In addition, since steps c) to e) also form part of the conventional siliciding process, implementation of the invention may therefore require only one additional step compared with the fabrication of an MOS transistor according to the prior art, namely the implantation step a).

In practice, with implantation of GE⁺ ions, it has been found that there is a reduction by a factor of 100 in junction leakage in an MOS transistor, compared with the implementation of a process according to the prior art.

By correctly choosing the implanted Ge⁺ ion dose, it is possible furthermore to reduce the layer resistances by 30%.

### BRIEF DESCRIPTION OF THE SEVERAL VIEWS OF THE DRAWING(S)

Other features and advantages of the invention will become more apparent on reading the description that follows. This is purely illustrative and must be read in conjunction with the appended drawings in which:

FIGS. 1 to 6 are sectional views for illustrating various steps in the implementation of a process according to the invention.

### DETAILED DESCRIPTION OF THE INVENTION

In the drawings, identical elements bear the same references. Each figure shows a sectional view of a transistor 10, which is an MOS transistor produced on the surface of a semiconductor wafer, forming a silicon substrate 1.

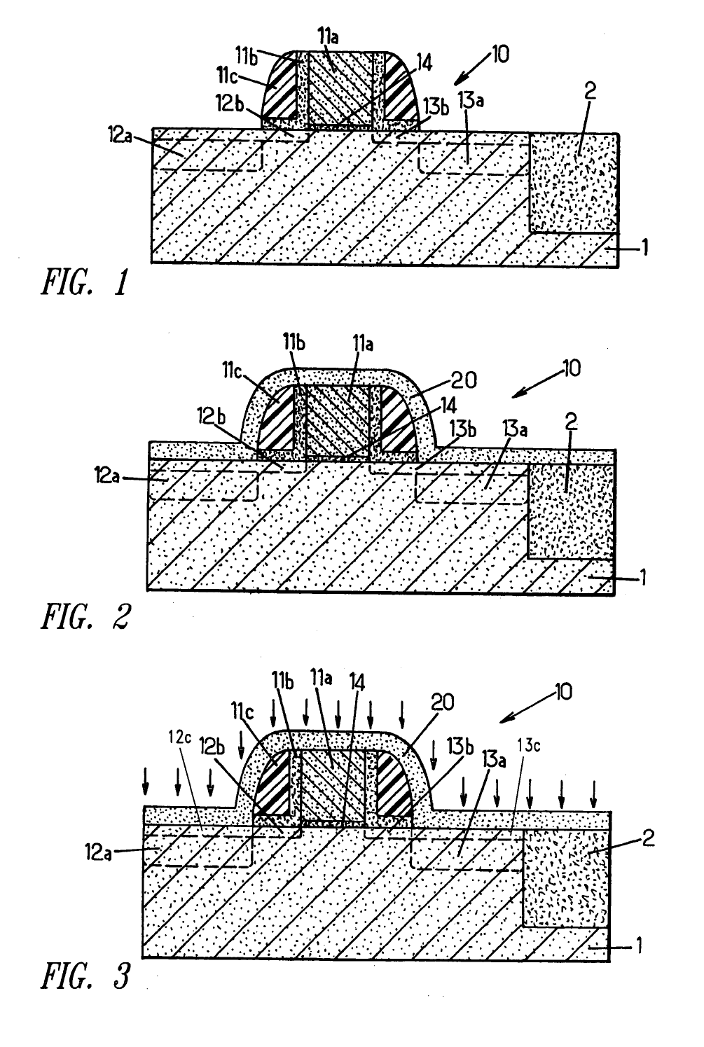

The diagram in FIG. 1 shows the transistor 10 before the start of the siliciding process according to the invention.

The gate of the transistor 10 comprises a polycrystalline silicon (polysilicon) layer 11 a or an amorphous silicon layer used as main conducting layer. The layer 11 a is attached to the surface of the substrate 1, from which it is isolated by a thin gate oxide layer 14, for example made of silicon dioxide (SiO₂). The main conducting layer 11a and the layer of insulation 14 are surrounded by a nitride layer 11b lying perpendicular to the surface of the substrate 1. The layer 11b also includes a part lying parallel to the surface of the substrate 1, extending away from the layers 11a and 14. The nitride may be silicon nitride (Si₃N₄). Finally, the gate of the transistor 10 includes a spacer 11c, formed from a portion of oxide (for example SiO₂) covering the entire nitride layer 11b.

Finally, the transistor comprises source and drain active regions formed by doped regions beneath the surface of the substrate 1. Typically, the source and drain regions comprise doped regions 12a and 13a extending down to a certain depth, starting from the boundaries of the spacer 11c on either side of the gate 11a. The portion of the substrate 1 lying between these regions 12a and 13a forms the channel of the transistor 10. Typically, the transistor furthermore includes regions 12b and 13b that are more lightly doped and of shallower depth than the regions 12a and 13a respectively, and lie parallel to the surface of the substrate 1, starting from the ends of the main conducting region 11a of the gate on either side of the latter. These regions 12b and 13b form LDD (Lightly Doped Drain) extensions. Finally, indicated in FIG. 1 is an STI (Shallow Trench Isolation) trench 2, for example made of SiO₂ whose function is to isolate the transistor 10 from the rest of the wafer.

In the first step illustrated by the diagram of FIG. 2, which is optional, an insulator layer 20 is formed on top of the transistor 10. This is a layer of dielectric, for example SiO₂ deposited by CVD (Chemical Vapor Deposition). The layer 20 is a conformal layer, in the sense that it follows the contours of the structure formed on the surface of the substrate 1.

The layer 20 may be deposited specifically for carrying out the process of the invention. As a variant, it may also act, in another operation, as mask formed from the stack of the said layer and of a nitride layer that is selectively etched, in order to protect certain transistors against the siliciding operation. In the latter case, the layer 20 is, for example, a layer of SiO₂ deposited by CVD using tetraethyl orthosilicate (TEOS). Such a mask is also called an “Si-Protect mask” in the jargon of those skilled in the art.

It should be noted that the layer 20 covers in particular the silicon regions of the transistor 10 that are exposed, namely the gate region 11a and part of the extensions 12b and 13b of the source and drain regions.

The next step, illustrated by the diagram of FIG. 3, involves the implantation of ions in the silicon regions to be silicided, that is to say in the regions 11a, regions 12c and 13c, which are parts of 12b and 13b starting from the ends of the spacers 11c on either sides of the spacers, where necessary through the oxide layer 20 down to a defined depth. The implanted ions are of a species that has the property of limiting the silicidation of metals.

This may be a wafer-scale implantation, thereby obviating the need for forming a specific mask.

Advantageously, the implanted ions may be non-dopant ions, and preferably heavy ions.

The ions may be selected from the group comprising Ge, Xe and Ar ions. It should be noted that these are non-dopant ions in so far as Ge has the same valency as silicon, and/or Xe and Ar are rare gases. Furthermore, Ge, Xe and Ar ions are heavy ions.

Under these conditions, such an implantation pre-amorphizes the silicon, with the consequence of destroying the implant residues that may have been introduced beforehand into the silicon, for example during implantation of dopant species through a mask formed from a photolithographically patterned resist.

It is possible for this implantation to be a wafer-scale implantation, in so far as, since the ions are non-dopant ions, they do not affect the electrical characteristics of the structures subjected to this implantation. As a variant, the implantation may, however, be limited to certain parts of the semiconductor wafer by using an appropriate mask.

In one example, the implanted ions being Ge⁺ ions, the implantation conditions may be defined by a concentration of between 10¹⁴ and 10¹⁶ particles per unit area, an implantation energy of between 5 and 50 keV, and ambient temperature. Such an implantation is at the present time an operation under the complete control of those skilled in the art and poses no particular problem.

By carrying out the implantation through the insulator layer 20, it is possible to limit the channeling of the ions in the silicon.

It is preferable to carry out a heat treatment, that is to say a heating step, in order to repair the formation of defects in the structure that is due to the implantation. Advantageously, this heating step may coincide with an annealing step to activate the dopant species pre-implanted in the gate region 11a and in the source and drain regions 12a-12b and 13a-13b of the transistor 10.

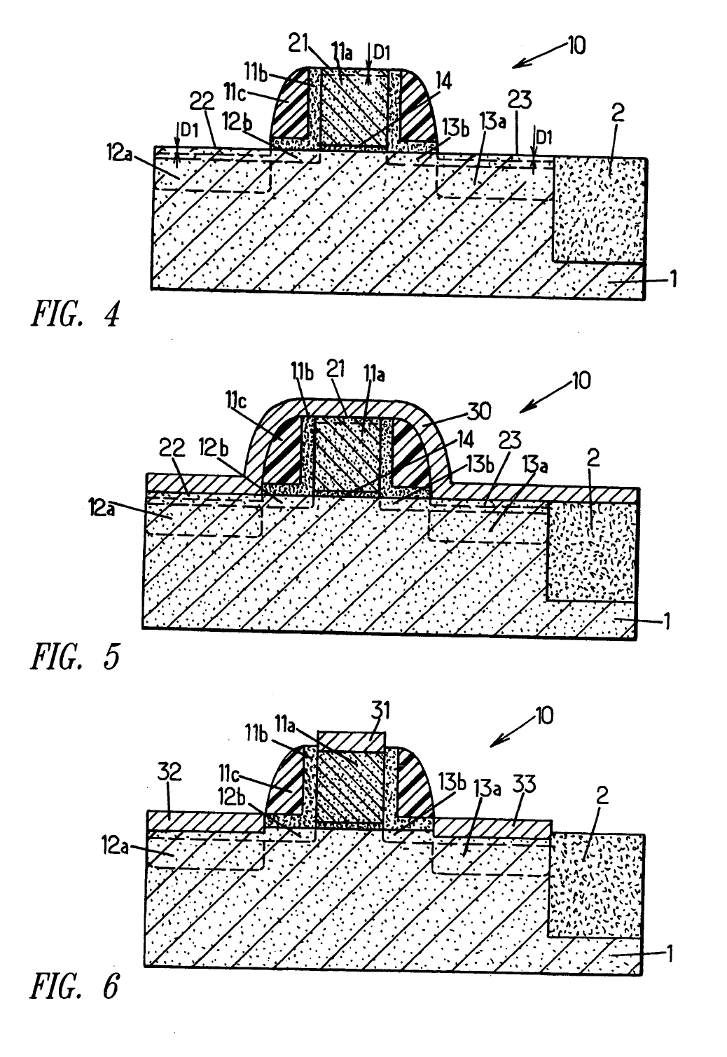

In the next step, the insulator layer 20 is removed by any appropriate process, for example by chemical etching, especially using hydrofluoric acid (HF). The configuration illustrated by the diagram of FIG. 4 is then obtained.

As may be seen in this figure, the ions implanted during the previous step have penetrated down to a defined depth D1 into the silicon regions to be silicided 11a, 12c and 13c, forming regions 21, 22 and 23. This depth is defined in particular by the implantation energy and the implantation dose, and by the thickness of the insulator layer 20 through which this implantation is carried out.

In the next steps, the conventional siliciding steps are carried out.

In the step illustrated by the diagram of FIG. 5, a layer 30 of metal capable of forming a silicide when it thermally reacts with silicon is thus deposited on the structure. This deposition may be carried out, for example, by sputtering.

In one example, the metal thus deposited is selected from the group consisting of Co, Ni, Pt, and Ti.

It should be noted that the layer 30 is also a conformal layer, in the sense that it follows the contours of the structure on the surface of the substrate 1.

Next, a thermal processing step, for example RTP (Rapid Thermal Processing), is carried out so as to make the metal of the layer 30 react on contact with the silicon of the underlying silicon parts 21, 22 and 23. This typically involves heating with a lamp. The reaction between the metal and the underlying silicon produces a silicide corresponding to the combination of silicon with the metal in question.

In the final step, the metal that has not reacted to the thermal processing of the previous step is removed, so as to obtain the configuration illustrated by the diagram of FIG. 6.

As may be seen, in the regions where the reaction between the metal and the silicon has taken place, respective silicide layers 31, 32 and 33 have formed on top of the silicon portions 11a, 12c and 13c. The depth of the layers 31, 32 and 33 in the substrate 1 is limited by the ion implantation depth D1. This is because the implanted ions act as an obstacle to the descent of the silicide into the silicon, owing to the fact that germanium silicide is difficult to obtain.

In other words, the depth of the silicide created is controlled by an appropriate choice of the implantation conditions for a given thickness of the insulator layer. In particular, the implantation energy may be varied in order to allow better control of the depth of the silicided regions 31, 32 and 33 within the respective silicon regions 11a, 12c and 13c on which they were formed.

It should be noted that implementation of the invention can be easily detected in semiconductor devices. This is because the presence of implanted ions in the silicided regions, more precisely beneath the silicide layers formed, may be detected. Compositional analysis may be carried out by SIMS (Secondary Ion Mass Spectroscopy) or by a technique for detecting impurities in the silicon, of the Auger type or the like. This analysis and this technique are well known to those skilled in the art.

The invention also relates to an MOS transistor obtained by implementing a process as described above. The transistor includes a silicide layer, for example above the gate, source and/or drain regions, and ions implanted in these regions just below the silicide layer, the said ions having the property of limiting the silicidation of metals.

Finally, the invention relates to a semiconductor device comprising an MOS transistor as described above.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for forming a silicide on top of a silicon portion on the surface of a semiconductor wafer, comprising the following steps:
a) implanting, at a defined depth in the silicon portion, of ions that have the property of limiting the silicidation of metals;
b) performing a heat treatment;
c) depositing a metal layer, said metal layer being capable of forming a suicide by thermal reaction with the silicon;
d) performing a rapid thermal processing suitable for siliciding the metal layer deposited at step c); and
e) removing metal from the metal layer that has not reacted to the thermal processing of step d);
wherein the thickness of the silicide created at step d) is controlled by an appropriate choice of the depth of the implantation carried out at step a).

2. A method according to claim 1 wherein the implantation of step a) is a wafer-scale implantation.

3. A method according to claim 1 wherein the ions implanted at step a) are non-dopant ions.

4. A method according to claim 1 wherein the ions implanted at step a) are heavy ions.

5. A method according to claim 3 wherein the ions implanted at step a) are selected from the group consisting of Ge, Xe and Ar ions.

6. A method according to claim 1 wherein the metal layer deposited at step c) is selected from the group consisting of Co, Ni, Pt, and Ti.

7. A method according to claim 1 wherein, at step a), the ions are implanted through a dielectric layer, which is removed during a removal step coming between steps b) and c).

8. A method according to claim 7 wherein the dielectric layer is an SiO₂ layer deposited using TEOS, said dielectric layer serving as a mask for another operation.

9. A method according to claim 1 wherein the heat treatment of step b) is an annealing treatment for activating dopant species implanted beforehand in the silicon portion and/or in other portions of the wafer.

10. A MOS transistor comprising:
a silicide layer on top of a defined region of silicon;
ions implanted into said region just below the silicide layer, said ions having the property of limiting the silicidation of metals.

11. A MOS transistor of claim 10 wherein the ions implanted are non-dopant ions.

12. A MOS transistor of claim 10 wherein the ions implanted are heavy ions.

13. A MOS transistor of claim 11 wherein the ions implanted are selected from the group consisting of Ge, Xe and Ar ions.

14. A process of forming a semiconductor device, comprising:
implanting silicide-limiting ions into a silicon region;
depositing a metal layer on the silicon region implanted with silicide-limiting ions; and
heating the metal layer such that a suicide layer is formed on the silicon region.

15. A process according to claim 14 wherein the silicide-limiting ions are non-dopant ions.

16. A process according to claim 14 wherein the silicide-limiting ions are heavy ions.

17. A process according to claim 15 wherein the silicide-limiting ions are selected from the group consisting of Ge, Xe and Ar ions.

18. A process according to claim 14, further comprising:
forming a dielectric layer on the silicon region, wherein said implanting step including implanting through said dielectric layer and removing said dielectric layer after the implanting step.
